(19) United States
(12) Patent Application Publication
(10) Pub. No.: US 2024/0365657 A1
(43) Pub. Date: Oct. 31, 2024

(54) PHOTOELECTRIC CONVERSION ELEMENT, IMAGING DEVICE, AND FULLERENE DERIVATIVE SOLUTION

(71) Applicant: Panasonic Intellectual Property Management Co., Ltd., Osaka (JP)

(72) Inventors: SEIJI TAKAGI, Osaka (JP); YUKO KISHIMOTO, Osaka (JP)

(21) Appl. No.: 18/764,143

(22) Filed: Jul. 3, 2024

Related U.S. Application Data
(63) Continuation of application No. PCT/JP2022/046922, filed on Dec. 20, 2022.

(30) Foreign Application Priority Data
Jan. 24, 2022 (JP) 2022-008898

(51) Int. Cl. H10K 85/20; H10K 30/20; H10K 39/32; H10K 85/10

(52) U.S. Cl. CPC H10K 85/215; H10K 30/211; H10K 39/32; H10K 85/111

(57) ABSTRACT

A photoelectric conversion element includes: a first electrode; a second electrode opposite to the first electrode; and a photoelectric conversion layer located between the first electrode and the second electrode. The photoelectric conversion layer contains a donor semiconductor, a first fullerene derivative, a second fullerene derivative different in molecular structure from the first fullerene derivative, and a polymer. The polymer contains at least one selected from the group consisting of polyvinylcarbazole, poly(triarylamine), polyfluorene, a polyvinylcarbazole derivative, a poly(triarylamine) derivative, and a polyfluorene derivative.

### BACKGROUND

### 1. Technical Field

The present disclosure relates to a photoelectric conversion element, an imaging device, and a fullerene derivative solution.

### 2. Description of the Related Art

Organic semiconductor materials have physical properties, functions, and the like that known inorganic semiconductor materials such as silicon do not have. For this reason, as semiconductor materials that can achieve novel semiconductor devices and electronic devices, organic semiconductor materials are actively studied these days.

For example, it has been studied to achieve photoelectric conversion elements by forming thin films of organic semiconductor materials and using the thin films as photoelectric conversion materials. Photoelectric conversion elements using organic material thin films can be utilized as optical sensors such as solid-state image sensors by taking out charge generated by light as electrical signals (see, for example, Japanese Patent No. 5969843).

In addition, fullerene derivatives represented by phenyl-C₆₁-butyric acid methyl ester ([60]PCBM) have been widely used as acceptor materials for photoelectric conversion elements using organic semiconductor materials. It has been known that fullerene derivatives easily aggregate and are thus crystallized by energy such as heat (see, for example, Samuele Lilliu et. al., “Dynamics of Crystallization and Disorder during Annealing of P3HT/PCBM Bulk Heterojunctions”, Macromolecules, American Chemical Society, 2011, Vol. 44, p. 2725-2734 (Non-Patent Literature 1)).

### SUMMARY

In one general aspect, the techniques disclosed here feature a photoelectric conversion element including: a first electrode; a second electrode opposite to the first electrode; and a photoelectric conversion layer located between the first electrode and the second electrode. The photoelectric conversion layer contains a donor semiconductor, a first fullerene derivative, a second fullerene derivative different in molecular structure from the first fullerene derivative, and a polymer. The polymer contains at least one selected from the group consisting of polyvinylcarbazole, poly(triarylamine), polyfluorene, a polyvinylcarbazole derivative, a poly(triarylamine) derivative, and a polyfluorene derivative.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic sectional view illustrating a photoelectric conversion element according to an embodiment;

FIG. 2 is a flowchart of a method for manufacturing a photoelectric conversion layer in the photoelectric conversion element according to the embodiment;

FIG. 3 is an illustrative energy band diagram in the photoelectric conversion element according to the embodiment;

FIG. 4 is a diagram illustrating an example of a circuit configuration of an imaging device according to the embodiment;

FIG. 5 is a schematic sectional view illustrating an example of a device structure of a pixel in the imaging device according to the embodiment;

FIG. 6 is a diagram illustrating an example of schematic current-voltage properties of the photoelectric conversion layer according to the embodiment;

FIG. 7 is a diagram illustrating part of a schematic circuit configuration of the pixel according to the embodiment;

FIG. 8 is a timing chart illustrating an example of a voltage applied to a second electrode of a photoelectric converter according to the embodiment and timings of operations in each row of a pixel array of the imaging device;

FIG. 9 is a diagram illustrating a result of measuring a particle size distribution of a fullerene derivative solution in Comparative Example 6;

FIG. 10 is a diagram illustrating a result of measuring a particle size distribution of a fullerene derivative solution in Comparative Example 7; and

FIG. 11 is a diagram illustrating a result of measuring a particle size distribution of a fullerene derivative solution in Example 10.

### DETAILED DESCRIPTIONS

In the case of using organic semiconductor materials for photoelectric conversion elements, it is desired to improve the reliability of the photoelectric conversion elements against light and heat. In particular, since it is known that crystallization of fullerene derivatives proceeds due to energy such as heat, such improvements have been challenges in using organic semiconductor materials for photoelectric conversion elements and the like. For example, in portions where crystals have been generated in a photoelectric conversion layer, electrical properties of the material change. For this reason, such crystals affect the device properties as well, and images obtained are affected in an imaging device such as an image sensor in particular.

The present disclosure provides a photoelectric conversion element and the like that can improve reliability.

### Underlying Knowledge Forming Basis of Aspects of the Present Disclosure

In organic semiconductor materials, if the molecular structure of an organic compound used is changed, the energy level can change. For this reason, for example, when organic semiconductor materials are used as photoelectric conversion materials, it is possible to control the absorption wavelength, and to thus provide a spectral sensitivity even in a near-infrared region where silicon (Si) does not have a spectral sensitivity. That is, using organic semiconductor materials makes it possible to utilize light in a wavelength range which has not been used in photoelectric conversion, and to achieve an increase in efficiency of solar cells and to achieve optical sensors and the like to be used in a near-infrared region. Hence, nowadays, photoelectric conversion elements and imaging devices using organic semiconductor materials are actively studied. Hereinafter, a photoelectric conversion element using an organic semiconductor is sometimes referred to as an “organic photoelectric conversion element”.

However, organic semiconductor materials are less durable against light and heat than Si, which is an inorganic material, and many organic semiconductor materials react and/or aggregate due to some energy. As disclosed in Non-Patent Literature 1, it is known that [60]PCBM, which is a fullerene derivative being widely studied for organic photoelectric conversion elements, is aggregated and crystallized due to heat.

Once a fullerene derivative is crystallized, the electrical properties such as carrier mobility and optical properties such as transmittance of that crystallized portion change. Hence, the charge transfer state and light absorption feature as a photoelectric conversion element change, and the reliability of the organic photoelectric conversion element decreases due to heat. In the case where a photoelectric conversion element is used for an imaging device, for example, aggregation of a fullerene derivative causes defects, bringing about an increase in dark current. Hence, to suppress changes caused by heat and the like, that is, changes that cause a decrease in reliability of an organic photoelectric conversion element, and to thus improve the reliability, it is important to make a fullerene derivative unlikely to aggregate.

As a result of conducting earnest studies based on such findings, the present inventors found that in photoelectric conversion elements which use fullerene derivatives for photoelectric conversion layers, it is possible to suppress aggregations of the fullerene derivatives by using two types of fullerene derivatives and a polymer in a photoelectric conversion layer.

In view of this, the present disclosure provides a photoelectric conversion element and the like that can suppress changes in properties which are caused by heat or the like and improve the reliability even in the case of using fullerene derivatives as acceptor materials.

### Overview of the Present Disclosure

The overview of one aspect of the present disclosure is as follows.

A photoelectric conversion element according to one aspect of the present disclosure includes: a first electrode; a second electrode opposite to the first electrode; and a photoelectric conversion layer located between the first electrode and the second electrode. The photoelectric conversion layer contains a donor semiconductor, a first fullerene derivative, a second fullerene derivative different in molecular structure from the first fullerene derivative, and a polymer. The polymer contains at least one selected from the group consisting of polyvinylcarbazole, poly(triarylamine), polyfluorene, a polyvinylcarbazole derivative, a poly(triarylamine) derivative, and a polyfluorene derivative.

This makes it possible to suppress aggregations of the fullerene derivatives and make crystallization of fullerene derivatives unlikely to occur. Therefore, it is possible to improve the reliability of the photoelectric conversion element according to the present aspect. In addition, this makes it possible to suppress aggregations of the fullerene derivatives while suppressing an influence of the polymer to the photoelectric conversion properties.

In addition, a fullerene derivative solution according to one aspect of the present disclosure includes: a first fullerene derivative; a second fullerene derivative different in molecular structure from the first fullerene derivative; a polymer; and a solvent. In the fullerene derivative solution, the number of particles each having a particle size of greater than or equal to 1 μm is less than 5% of a total number of particles.

This makes it possible to achieve a fullerene derivative solution in which aggregations of the fullerene derivatives are suppressed. Hence, for example, it is possible to form a photoelectric conversion layer in which aggregations of the fullerene derivatives are suppressed by forming the photoelectric conversion layer by using the fullerene derivative solution according to the present aspect. Therefore, it is possible to improve the reliability of a photoelectric conversion element including the photoelectric conversion layer thus formed.

In addition, for example, the first fullerene derivative may be one selected from the group consisting of phenyl-C₆₁-butyric acid methyl ester ([60]PCBM), phenyl-C₇₁-butyric acid methyl ester ([70]PCBM), phenyl-C₆₁-butyric acid butyl ester ([60]PCBB), phenyl-C₆₁-butyric acid octyl ester ([60]PCBO), and phenyl-C₆₁-butyric acid dodecyl ester ([60]PCBD), and the second fullerene derivative may be another one selected from the group consisting of phenyl-C₆₁-butyric acid methyl ester, phenyl-C₇₁-butyric acid methyl ester, phenyl-C₆₁-butyric acid butyl ester, phenyl-C₆₁-butyric acid octyl ester, and phenyl-C₆₁-butyric acid dodecyl ester. In addition, for example, the first fullerene derivative may be [60]PCBM, and the second fullerene derivative may be [70]PCBM.

This makes it possible to effectively suppress aggregations of the fullerene derivatives.

In addition, for example, the number of carbon atoms of a fullerene skeleton of the first fullerene derivative may be different from the number of carbon atoms of a fullerene skeleton of the second fullerene derivative.

This allows cohesion between the first fullerene derivative and the second fullerene derivative to easily decrease and makes it possible to effectively suppress aggregations of the fullerene derivatives.

In addition, for example, in the case where the first fullerene derivative is [60]PCBM and the second fullerene derivative is [70]PCBM, a ratio by weight of the second fullerene derivative to the first fullerene derivative may be greater than or equal to 10/90 and less than or equal to 30/70.

This increases [60]PCBM having a deeper Highest-Occupied-Molecular-Orbital (HOMO) energy level to make an unintentional transfer of charge from the donor material less easily occur and thus makes it possible to reduce dark current.

In addition, for example, a ratio by weight of the polymer to a total weight of the first fullerene derivative and the second fullerene derivative may be greater than or equal to 1/30 and less than or equal to 30/70.

This makes it possible to suppress a decrease in photoelectric conversion properties while maintaining dispersion of the fine particle state (for example, nanosize) of the fullerene derivatives.

In addition, for example, the polymer may be an organic semiconductor.

This makes transfer of charge generated through photoelectric conversion of the photoelectric conversion layer unlikely to be hindered by the polymer and thus makes it possible to suppress a decrease in photoelectric conversion properties.

In addition, for example, a weight average molecular weight of the polymer may be greater than or equal to 50000.

This increases a viscosity of a solution in the case of forming a photoelectric conversion layer by using the fullerene derivative solution containing the polymer and thus improves an applicability of the solution at the time of forming the photoelectric conversion layer such as making it easy to adjust a film thickness of the photoelectric conversion layer.

In addition, for example, the solvent may contain at least one selected from the group consisting of benzene, toluene, xylene, anisole, chlorobenzene, chloronaphthalene, chlorophenol, tetralin, and chloroform.

This allows each material of the fullerene derivative solution to be easily dissolved or dispersed and thus makes it possible to effectively suppress aggregations of the fullerene derivatives in the fullerene derivative solution.

In addition, an imaging device according to one aspect of the present disclosure includes: a photoelectric converter that generates charge through photoelectric conversion; and a charge detecting circuit that is connected to the photoelectric converter. The photoelectric converter includes the above-described photoelectric conversion element.

This allows the imaging device to comprise the photoelectric converter including the above-described photoelectric conversion element and makes it possible to improve the reliability of the imaging device.

Hereinafter, embodiments of the present disclosure will be specifically described with reference to the drawings.

Note that any of embodiments described below illustrates a comprehensive or specific example. Numerical values, shapes, constituents, arrangement positions and connection forms of the constituents, steps, the orders of the steps, and the like shown in the following embodiments are mere examples and are not intended to limit the present disclosure. In addition, among constituents in the following embodiments, constituents that are not stated in independent claims are described as optional constituents. In addition, each drawing is not necessarily strictly illustrated. In the drawings, substantially same configurations are denoted by the same signs, and repetitive description is omitted or simplified in some cases.

In addition, in the present specification, terms expressing relations among elements and terms expressing shapes of elements as well as numerical ranges are not expressions representing only strict means but expressions that mean to encompass substantially same ranges, for example, differences of around several %.

In addition, in the present specification, terms “above” and “below” do not indicate an upper direction (vertically above) and a lower direction (vertically below) in an absolute space recognition, but are used as terms specified by relative positional relations based on a stacking order in a stack configuration. Note that terms such as “above” and “below” are used only to designate relative arrangements of members, and are not intended to limit the orientations in use of the photoelectric conversion element and the imaging device. In addition, terms “above” and “below” are applied to not only cases where two constituents are arranged at an interval from each other and another constituent is present between the two constituents but also cases where two constituents are arranged in close contact with each other, so that the two constituents are in contact with each other.

### EMBODIMENTS

### Photoelectric Conversion Element

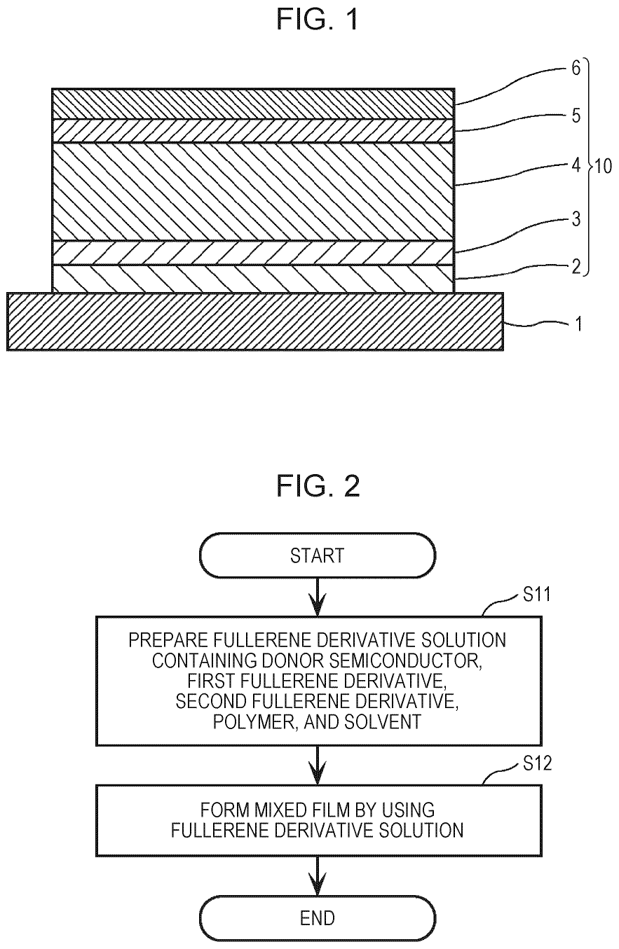

First, a photoelectric conversion element according to the present embodiment will be described by using FIG. 1. The photoelectric conversion element according to the present embodiment is, for example, a photoelectric conversion element of charge reading type. FIG. 1 is a schematic sectional view illustrating the photoelectric conversion element 10 according to the present embodiment.

As illustrated in FIG. 1, the photoelectric conversion element 10 is supported by a support substrate 1. The photoelectric conversion element 10 includes a first electrode 2 and a second electrode 6 disposed on the opposite side to the first electrode 2, which are a pair of electrodes, and a photoelectric conversion layer 4 located between the first electrode 2 and the second electrode 6. The photoelectric conversion element 10 further includes a hole blocking layer 5 located between the second electrode 6 and the photoelectric conversion layer 4, and an electron blocking layer 3 located between the first electrode 2 and the photoelectric conversion layer 4. Note that the photoelectric conversion element 10 only has to include at least the first electrode 2, the second electrode 6, and the photoelectric conversion layer 4 and does not have to include at least one of the hole blocking layer 5 or the electron blocking layer 3.

Hereinafter, each constituent of the photoelectric conversion element 10 according to the present embodiment will be described.

The support substrate 1 only has to be a substrate used in general photoelectric conversion elements, and may be, for example, a glass substrate, a quartz substrate, a semiconductor substrate, a plastic substrate, or the like.

The first electrode 2 is formed of a metal, a metal nitride, a metal oxide, polysilicon provided with an electrical conductivity, or the like. Examples of the metal include aluminum, copper, titanium, tungsten, and the like. An example of a method for providing polysilicon with an electrical conductivity includes doping polysilicon with impurities.

The second electrode 6 is a transparent electrode formed of, for example, a transparent electrically conductive material. The materials of the second electrode 6 includes, for example, Transparent Conducting Oxide (TCO), Indium Tin Oxide (ITO), Indium Zinc Oxide (IZO), Aluminum-doped Zinc Oxide (AZO), Fluorine-doped Tin Oxide (FTO), SnO₂, TiO₂, and the like. Note that the second electrode 6 may be fabricated by combining TCO with one or more metal materials such as aluminum (Al) and gold (Au) in accordance with a desired transmittance. Note that term “transparent” in the present specification means that at least part of light having a wavelength which the photoelectric conversion layer 4 can absorb is transmitted, and it is not essential that light is transmitted over the entire wavelength range. In addition, in the present specification, all electromagnetic waves including visible light, infrared light, and ultraviolet light are expressed as “light” for convenience.

Note that the materials of the first electrode 2 and the second electrode 6 are not limited to the above-mentioned electrically conductive materials, and other materials may be used. For example, the first electrode 2 may be a transparent electrode.

Various methods are used to fabricate the first electrode 2 and the second electrode 6 depending on a material used. For example, in the case of using ITO, an electron beam method, a sputtering method, a resistance heating evaporation method, a chemical reaction method such as a sol-gel method, a method including application of a dispersion of indium tin oxide, and the like may be used. In this case, in the fabrication of the first electrode 2 and the second electrode 6, a UV-ozone treatment, a plasma treatment or the like may be conducted after an ITO film is formed.

To the first electrode 2 and the second electrode 6, for example, a bias voltage is applied through lines (not illustrated). For example, the polarity of the bias voltage is determined such that among charge generated in the photoelectric conversion layer 4, electrons move to the second electrode 6 and holes move to the first electrode 2. An example in which electrons move to the second electrode 6 and holes move to the first electrode 2 will be described below. Note that a bias voltage may be set such that among charge generated in the photoelectric conversion layer 4, holes move to the second electrode 6 and electrons move to the first electrode 2.

The photoelectric conversion layer 4 is, for example, a mixed film having a bulk hetero structure containing a donor semiconductor and an acceptor semiconductor. In addition, the photoelectric conversion layer 4 further contains a polymer. The photoelectric conversion layer 4 contains two types of fullerene derivatives, which are a first fullerene derivative and a second fullerene derivative different in molecular structure from the first fullerene derivative, as the acceptor semiconductor. In addition, the photoelectric conversion layer 4 contains, for example, a donor organic semiconductor material as the donor semiconductor. As the photoelectric conversion layer 4 contains two types of fullerene derivatives, which are the first fullerene derivative and the second fullerene derivative, their different molecular structures allow the first fullerene derivative and the second fullerene derivative to suppress each other's aggregations. Moreover, as the photoelectric conversion layer 4 contains a polymer, the polymer penetrates between the fullerene derivatives to suppress aggregations of the fullerene derivatives due to heat or the like. Therefore, aggregations of the fullerene derivatives are effectively suppressed in the photoelectric conversion layer 4.

Hereinafter, the details of the donor semiconductor, the fullerene derivatives, and the polymer will be described.

The donor organic semiconductor material used as the donor semiconductor includes, for example, triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, naphthalocyanine compounds, subphthalocyanine compounds, cyanine compounds, merocyanine compounds, oxonol compounds, polyamine compounds, indole compounds, pyrrole compounds, pyrazole compounds, polyarylene compounds, condensed aromatic carbocyclic compounds (for example, naphthalene derivatives, anthracene derivatives, phenanthrene derivatives, tetracene derivatives, pyrene derivatives, perylene derivatives, fluoranthene derivative s, and the like) and metal complexes having a nitrogen-containing heterocyclic compound as a ligand, and the like.

In addition, the donor semiconductor is not limited to the above-described examples but may be, for example, a silicon semiconductor, a compound semiconductor, a quantum dot, a perovskite material, a carbon nanotube, or the like, or may be a mixture of these.

The fullerene derivatives used as the first fullerene derivative and the second fullerene derivative include, for example, [60]PCBM, phenyl-C₇₁-butyric acid methyl ester ([70]PCBM), phenyl-C₆₁-butyric acid butyl ester ([60]PCBB), phenyl-C₆₁-butyric acid octyl ester ([60]PCBO), phenyl-C₆₁-butyric acid dodecyl ester ([60]PCBD), bis-phenyl-C₆₁-butyric acid methyl ester (Bis-PCBM), and indene-C₆₀ bisadduct (ICBA), and the like.

The first fullerene derivative may be, for example, one of [60]PCBM, [70]PCBM, [60]PCBB, [60]PCBO, and [60]PCBD. The second fullerene derivative may be, for example, another one of [60]PCBM, [70]PCBM, [60]PCBB, [60]PCBO, and [60]PCBD. In addition, among these, the first fullerene derivative may be [60]PCBM and the second fullerene derivative may be [70]PCBM. This makes it possible to effectively suppress aggregations of the fullerene derivatives.

In the case where the first fullerene derivative is [60]PCBM and the second fullerene derivative is [70]PCBM, a ratio by weight of the second fullerene derivative to the first fullerene derivative is, for example, greater than or equal to 1/99 and less than or equal to 50/50 and may be greater than or equal to 10/90 and less than or equal to 30/70. This makes the weight of [60]PCBM having a deeper HOMO energy level greater than or equal to the weight of [70]PCBM to make an unintentional transfer of charge from the donor semiconductor unlikely to occur and thus makes it possible to reduce dark current.

In addition, the number of carbon atoms of a fullerene skeleton of the first fullerene derivative and the number of carbon atoms of a fullerene skeleton of the second fullerene derivative may be different. This makes the structure of a fullerene skeleton, which would increase cohesion of a fullerene derivative, different between the first fullerene derivative and the second fullerene derivative. As a result, the first fullerene derivative and the second fullerene derivative can easily suppress each other's aggregations, and aggregations of the fullerene derivatives can be effectively suppressed.

The polymer may be a polymer material that can be dissolved in a solvent in which the donor organic semiconductor material, the first fullerene derivative, and the second fullerene derivative are dissolved or dispersed. The polymer contains, for example, a polymer compound having an aromatic ring. It is surmised that this allows the aromatic ring to interact with the fullerene skeletons to effectively suppress aggregations of the fullerene derivatives.

A specific material of the polymer includes, for example, polystyrene, polyvinylcarbazole, poly(triarylamine), polyfluorene, polythiophene, and derivatives of these. The polymer may be a material other than those given here or may be a mixture of a plurality of materials. Among these, the polymer contains, for example, at least one of polyvinylcarbazole, poly(triarylamine), polyfluorene, polythiophene, or derivatives of these. This makes it possible to effectively suppress aggregations of the fullerene derivatives.

The polymer is, for example, an organic semiconductor. With this, the organic semiconductor allows charge to be transported in the photoelectric conversion layer 4 and is unlikely to hinder the transport of charge in the photoelectric conversion layer 4, thus making it possible to suppress aggregations of the fullerene derivatives while suppressing an influence on the photoelectric conversion properties. In addition, in the case where the polymer is an organic semiconductor, the band gap of the organic semiconductor is, for example, greater than or equal to 3.0 eV.

In addition, the polymer is, for example, transparent to light having a component in the absorption wavelength of the donor semiconductor. The polymer is, for example, transparent to a wavelength range of at least part of the wavelength range from visible light to near-infrared light. This makes it possible to suppress a decrease in photoelectric conversion efficiency of the photoelectric conversion element 10 which would be caused by the polymer absorbing light even when the polymer is contained in the photoelectric conversion layer 4. At a wavelength of at least part of the absorption wavelength of the donor semiconductor, for example, the polymer has a smaller absorbance of the wavelength of at least part than the donor semiconductor.

A weight average molecular weight of the polymer is, for example, greater than or equal to 10000, and may be greater than or equal to 50000. In the case of forming the photoelectric conversion layer 4 by using a fullerene derivative solution as described later, this increases a viscosity of the fullerene derivative solution and thus makes it easy to adjust the film thickness of the photoelectric conversion layer 4 to be formed. In addition, the weight average molecular weight of the polymer is, for example, less than or equal to 1000000.

A ratio by weight of the polymer to a total weight of the first fullerene derivative and the second fullerene derivative is, for example, greater than or equal to 1/30 and less than or equal to 30/30, and may be greater than or equal to 1/30 and less than or equal to 30/70. This makes it possible to suppress a decrease in photoelectric conversion properties while effectively suppressing aggregations of the fullerene derivatives.

The photoelectric conversion layer 4 is formed, for example, by using a fullerene derivative solution. FIG. 2 is a flowchart of a method for manufacturing the photoelectric conversion layer 4 in the photoelectric conversion element 10 according to the present embodiment.

As illustrated in FIG. 2, in the manufacture of the photoelectric conversion layer 4, first, a fullerene derivative solution containing a donor semiconductor, a first fullerene derivative, a second fullerene derivative, a polymer, and a solvent is prepared (step S11).

For example, materials of the donor semiconductor, the first fullerene derivative, the second fullerene derivative, and the polymer are weighed. These materials thus weighed are added to a solvent, followed by stirring to prepare the fullerene derivative solution. By using two types of fullerene derivatives and a polymer as materials in this way, a fullerene derivative solution in which aggregations of the fullerene derivatives are suppressed can be prepared. Note that in the present specification, the fullerene derivative solution does not have to be a solution in which the contained materials are completely dissolved in the solvent, and at least part of the materials may be dispersed in the form of particles in the fullerene derivative solution. For example, during a period when the fullerene derivative solution is used in the manufacturing steps, precipitation or the like of dispersed particles substantially does not occur, and a uniform state in the solution is maintained.

The solvent is not particularly limited as long as the donor semiconductor, the first fullerene derivative, the second fullerene derivative, and the polymer are dissolved or dispersed in the solvent. The solvent contains, for example, at least one of benzene, toluene, xylene, anisole, chlorobenzene, chloronaphthalene, chlorophenol, tetralin, or chloroform. This allows each material of the fullerene derivative solution to be easily dissolved or dispersed, so that aggregations of the fullerene derivatives in the fullerene derivative solution can be effectively suppressed. The main component of the solvent is, for example, any of benzene, toluene, xylene, anisole, chlorobenzene, chloronaphthalene, chlorophenol, tetralin, and chloroform.

The materials used as the donor semiconductor, the first fullerene derivative, the second fullerene derivative and the polymer are as mentioned above.

Next, in the manufacture of the photoelectric conversion layer 4, a mixed film is formed as the photoelectric conversion layer 4 by using the fullerene derivative solution thus prepared (step S12). For example, a mixed film is formed by applying the fullerene derivative solution to a region where the photoelectric conversion layer 4 is to be formed, by using an application method such as spin-coating or inkjet to form a coated film, and drying the coated film.

By using such a fullerene derivative solution containing two types of fullerene derivatives, which are the first fullerene derivative and the second fullerene derivative, and the polymer in the manufacture of the photoelectric conversion layer 4, aggregations of the fullerene derivatives in the fullerene derivative solution are suppressed. Hence, the photoelectric conversion layer 4 in which aggregations of the fullerene derivatives are suppressed can be formed. In addition, since the polymer is contained also in the photoelectric conversion layer 4 thus formed, the polymer penetrates between the fullerene derivatives to suppress aggregations of the fullerene derivatives due to heat or the like even after the photoelectric conversion layer 4 is formed.

Note that the fullerene derivative solution prepared in step S11 does not have to contain the donor semiconductor. In this case, in step S12, after the donor semiconductor is added to the fullerene derivative solution, a mixed film is formed by using the fullerene derivative solution to which the donor semiconductor has been added. In addition, the photoelectric conversion layer 4 may have a multi-layer structure including an acceptor semiconductor layer formed by using a fullerene derivative solution that does not contain the donor semiconductor, and a donor semiconductor layer.

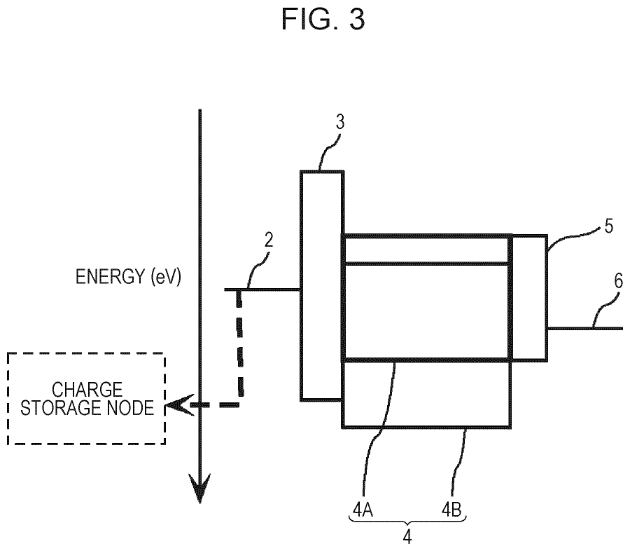

FIG. 3 is an illustrative energy band diagram in the photoelectric conversion element 10 illustrated in FIG. 1. In FIG. 3, an energy band of each layer is indicated by a rectangle.

The photoelectric conversion layer 4 when irradiated with light generates pairs of electrons and holes. Each pair of an electron and a hole thus generated is separated into the electron and the hole by an electric field applied to the photoelectric conversion layer 4, and each moves toward the first electrode 2 or the second electrode 6 in accordance with the electric field. Here, a material that supplies the other material with the electron of a pair of an electron and a hole generated by absorption of light is referred to as a donor material, and a material that receives the electron is referred to as an acceptor material. In the case of using two different types of organic semiconductors, which of them becomes a donor material and which of them becomes an acceptor material are generally determined by relative positions of Highest-Occupied-Molecular-Orbital (HOMO) and Lowest-Unoccupied-Molecular-Orbital (LUMO) energy levels of the respective two types of organic semiconductors at a contact interface. Specifically, as illustrated in FIG. 3, a material having a shallower LUMO energy level to receive electrons becomes a donor material 4A and a material having a deeper LUMO energy level becomes an acceptor material 4B. Of a rectangle indicating an energy band in FIG. 3, the upper end is a LUMO energy level, and the lower end is a HOMO energy level. In this way, since the photoelectric conversion layer 4 contains the donor material 4A and the acceptor material 4B, electrons and holes generated in the photoelectric conversion layer 4 are separated to the donor material 4A and the acceptor material 4B, so that it is difficult for electrons and holes to recombine. Hence, the photoelectric conversion efficiency of the photoelectric conversion element 10 can be improved.

In the present embodiment, the donor material 4A is the above-mentioned donor semiconductor, and the acceptor material 4B is the above-mentioned two types of fullerene derivatives. Note that FIG. 3 illustrates only an energy band of one fullerene derivative among the two types of fullerene derivatives for visibility. To be precise, there are two different energy levels of the acceptor material 4B; however, these have the same role, and both fullerene derivatives have deeper LUMO energy levels than the donor material 4A.

In addition, as illustrated in FIG. 3, the first electrode 2, when used for example in an imaging device, is electrically connected to a charge storage node.

As mentioned above, the photoelectric conversion element 10 according to the present embodiment includes the electron blocking layer 3, which is provided between the first electrode 2 and the photoelectric conversion layer 4, and the hole blocking layer 5, which is provided between the second electrode 6 and the photoelectric conversion layer 4. The electron blocking layer 3 and the hole blocking layer 5 are charge blocking layers which suppress injection of charge from the electrodes into the photoelectric conversion layer 4. By providing the electron blocking layer 3 and the hole blocking layer 5, injection of charge from the electrodes into the photoelectric conversion layer 4 can be suppressed, and noise signals which adversely affect signal-to-noise ratio (SNR) can be reduced.

Specifically, the electron blocking layer 3 is provided to reduce dark current which would be generated if electrons were injected from the first electrode 2 and suppresses injection of electrons from the first electrode 2 into the photoelectric conversion layer 4. In addition, the electron blocking layer 3 also has a function of transporting holes generated in the photoelectric conversion layer 4 to the first electrode 2. In addition, the hole blocking layer 5 is provided to reduce dark current which would be generated if holes were injected from the second electrode 6 and suppresses injection of holes from the second electrode 6 into the photoelectric conversion layer 4. In addition, the hole blocking layer 5 also has a function of transporting electrons generated in the photoelectric conversion layer 4 to the second electrode 6.

The electron blocking layer 3 and the hole blocking layer 5 are formed of, for example, organic semiconductor materials. The materials of the electron blocking layer 3 and the hole blocking layer 5 are not limited to organic semiconductor materials and may be inorganic semiconductor materials such as oxide semiconductors and nitride semiconductors or may be composite materials of these.

Note that in the photoelectric conversion element 10, in the case where holes move to the second electrode 6 and electrons move to the first electrode 2 among charge generated in the photoelectric conversion layer 4, the positions of the electron blocking layer 3 and the hole blocking layer 5 may be reversed. That is, the electron blocking layer 3 may be disposed between the second electrode 6 and the photoelectric conversion layer 4 and the hole blocking layer 5 may be disposed between the first electrode 2 and the photoelectric conversion layer 4.

### Imaging Device

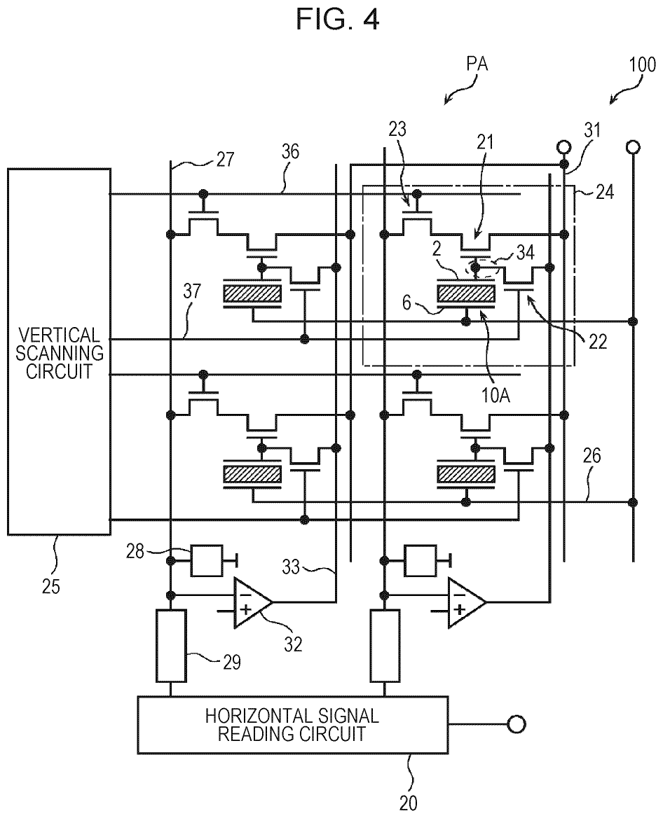

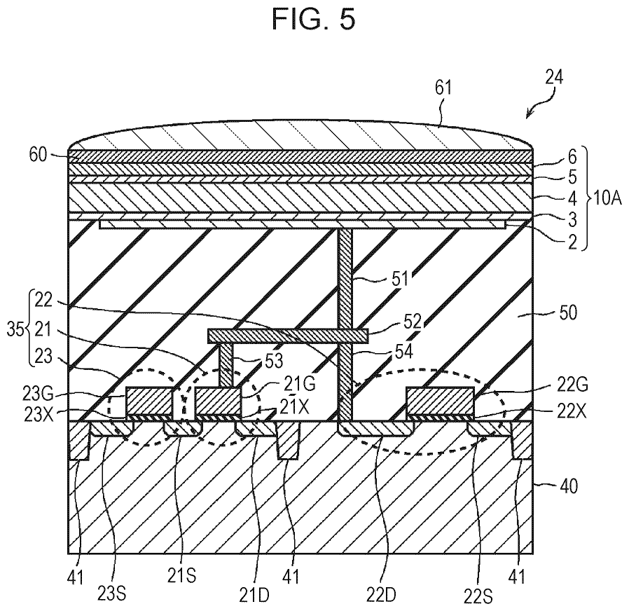

Hereinafter, an imaging device according to the present embodiment will be described by using FIG. 4 and FIG. 5. FIG. 4 is a diagram illustrating an example of a circuit configuration of an imaging device 100 which incorporates a photoelectric converter 10A using the photoelectric conversion element 10 illustrated in FIG. 1. In addition, FIG. 5 is a schematic sectional view illustrating an example of a device structure of a pixel 24 in the imaging device 100 according to the present embodiment.

As illustrated in FIG. 4 and FIG. 5, the imaging device 100 according to the present embodiment includes: a semiconductor substrate 40; and a pixel 24 including a charge detecting circuit 35 provided on the semiconductor substrate 40, a photoelectric converter 10A provided above the semiconductor substrate 40, and a charge storage node 34 electrically connected to the charge detecting circuit 35 and the photoelectric converter 10A. The photoelectric converter 10A of the pixel 24 includes the above-described photoelectric conversion element 10. The charge storage node 34 stores charge obtained in the photoelectric converter 10A. The charge detecting circuit 35 is connected to the photoelectric converter 10A via the charge storage node 34 and detects charge stored in the charge storage node 34. Note that the charge detecting circuit 35 provided on the semiconductor substrate 40 may be provided above the semiconductor substrate 40 or may be provided directly in the semiconductor substrate 40.

As illustrated in FIG. 4, the imaging device 100 includes a plurality of the pixels 24 and peripheral circuits. The imaging device 100 is an organic image sensor achieved by a one chip-integrated circuit, and has a pixel array PA including the plurality of pixels 24 which are two-dimensionally arrayed.

The plurality of pixels 24 are arrayed two-dimensionally, that is, in the row direction and the column direction on the semiconductor substrate 40 to form a photosensitive region, which is a pixel region. FIG. 4 illustrates an example in which the pixels 24 are arrayed on a matrix of 2 rows by 2 columns. Note that in FIG. 4, an illustration of a circuit (for example, a pixel electrode control circuit) for individually setting sensitivities of the pixels 24 is omitted for illustration. In addition, the imaging device 100 may be a line sensor. In this case, the plurality of pixels 24 may be one-dimensionally arrayed. Note that in the present specification, the row direction and the column direction refer to directions in which rows and columns extend respectively. That is, in FIG. 4, the longitudinal direction is the column direction and the lateral direction is the row direction on the paper.

As illustrated in FIG. 4 and FIG. 5, each pixel 24 includes the photoelectric converter 10A and the charge storage node 34 electrically connected to the charge detecting circuit 35. The charge detecting circuit 35 includes an amplification transistor 21, a reset transistor 22, and an address transistor 23.

The photoelectric converter 10A includes the first electrode 2 provided as a pixel electrode and the second electrode 6 provided as a counter electrode. To the second electrode 6, a predetermined bias voltage is applied via a counter electrode signal line 26.

The first electrode 2 is connected to a gate electrode 21G of the amplification transistor 21, and signal charge collected by the first electrode 2 is stored in the charge storage node 34, which is located between the first electrode 2 and the gate electrode 21G of the amplification transistor 21. In the present embodiment, the signal charge is holes.

The signal charge stored in the charge storage node 34 is applied to the gate electrode 21G of the amplification transistor 21 as a voltage corresponding to the amount of the signal charge. The amplification transistor 21 amplifies this voltage, which is then selectively read by the address transistor 23 as a signal voltage. The reset transistor 22 has a source/drain electrode connected to the first electrode 2, and resets the signal charge stored in the charge storage node 34. In other words, the reset transistor 22 resets the potentials of the gate electrode 21G of the amplification transistor 21 and the first electrode 2.

To selectively conduct the above-mentioned operations in the plurality of pixels 24, the imaging device 100 includes power lines 31, vertical signal lines 27, address signal lines 36, and reset signal lines 37, and these lines are connected to the pixels 24. Specifically, the power line 31 is connected to a source/drain electrode of the amplification transistor 21, and the vertical signal line 27 is connected to a source/drain electrode of the address transistor 23. The address signal line 36 is connected to a gate electrode 23G of the address transistor 23. In addition, the reset signal line 37 is connected to a gate electrode 22G of the reset transistor 22.

The peripheral circuits include a vertical scanning circuit 25, a horizontal signal reading circuit 20, a plurality of column signal processing circuits 29, a plurality of load circuits 28, and a plurality of differential amplifiers 32.

The vertical scanning circuit 25 is connected to the address signal lines 36 and the reset signal lines 37, selects a plurality of pixels 24 disposed in each row on a row-by-row basis to read a signal voltage and reset the potential of the first electrode 2. The power line 31, which is a source follower power supply, supplies a predetermined power supply voltage to each pixel 24. The horizontal signal reading circuit 20 is electrically connected to the plurality of column signal processing circuits 29. The column signal processing circuit 29 is electrically connected to the pixels 24 disposed in each column via the vertical signal line 27 corresponding to the each column. The load circuit 28 is electrically connected to the corresponding vertical signal line 27. The load circuit 28 and the amplification transistor 21 form a source follower circuit.

The plurality of differential amplifiers 32 are provided in one-to-one correspondence with the respective columns. An input terminal on the negative side of the differential amplifier 32 is connected to the corresponding vertical signal line 27. In addition, an output terminal of the differential amplifier 32 is connected to the pixels 24 via a feedback line 33 corresponding to each column.

The vertical scanning circuit 25 applies row select signals for controlling on and off of the address transistors 23 to the gate electrodes 23G of the address transistors 23 via the address signal lines 36. This causes a row of reading target to be scanned and selected. Signal voltages are read from the pixels 24 of the selected row to the vertical signal line 27. In addition, the vertical scanning circuit 25 applies reset signals for controlling on and off of the reset transistors 22 to the gate electrodes 22G of the reset transistors 22 via the reset signal lines 37. This causes a row of pixels 24 subject to the reset operation to be selected. The vertical signal lines 27 transmit signal voltages read from the pixels 24 selected by the vertical scanning circuit 25 to the column signal processing circuits 29.

The column signal processing circuit 29 conducts noise suppression signal processing represented by correlated double sampling, analog-to-digital conversion (AD conversion), and the like.

The horizontal signal reading circuit 20 successively reads signals from the plurality of column signal processing circuits 29 to a horizontal common signal line (not illustrated).

The differential amplifier 32 is connected to a drain electrode of the reset transistor 22 via the feedback line 33. Hence, the differential amplifier 32 receives an output value of the address transistor 23 at a negative terminal. The differential amplifier 32 conducts a feedback operation such that the gate potential of the amplification transistor 21 becomes a predetermined feedback voltage. At this time, the output voltage value of the differential amplifier 32 is 0 V or a positive voltage near 0 V. The feedback voltage means an output voltage of the differential amplifier 32.

As illustrated in FIG. 5, the pixel 24 includes the semiconductor substrate 40, the charge detecting circuit 35, the photoelectric converter 10A, and the charge storage node 34 (see FIG. 4).

The semiconductor substrate 40 may be an insulating substrate or the like provided with a semiconductor layer on a surface on the side of which a photosensitive region is formed, and is, for example, a p-type silicon substrate. The semiconductor substrate 40 includes impurity regions 21D, 21S, 22D, 22S, and 23S and element isolating regions 41 for electrically isolating the pixels 24. The impurity regions 21D, 21S, 22D, 22S and 23S are, for example, n-type regions. Here, the element isolating regions 41 are each provided between the impurity region 21D and the impurity region 22D. This suppresses leakage of signal charge stored in the charge storage node 34. Note that the element isolating regions 41 are formed, for example, by conducting ion implantation of an acceptor under predetermined implantation conditions.

The impurity regions 21D, 215, 22D, 22S, and 23S are, for example, diffusion regions formed in the semiconductor substrate 40. As illustrated in FIG. 5, the amplification transistor 21 includes the impurity region 21S and the impurity region 21D as well as the gate electrode 21G. The impurity region 21S and the impurity region 21D function as, for example, a source region and a drain region of the amplification transistor 21, respectively. Between the impurity region 21S and the impurity region 21D, a channel region of the amplification transistor 21 is formed.

Similarly, the address transistor 23 includes the impurity region 23S and the impurity region 21S as well as the gate electrode 23G connected to the address signal line 36. In this example, the amplification transistor 21 and the address transistor 23 share the impurity region 21S to thus be electrically connected with each other. The impurity region 23S functions as, for example, a source region of the address transistor 23. The impurity region 23S has a connection with the vertical signal line 27 illustrated in FIG. 4.

The reset transistor 22 includes the impurity regions 22D and 22S as well as the gate electrode 22G connected to the reset signal line 37. The impurity region 22S functions as, for example, a source region of the reset transistor 22. The impurity region 22S has a connection with the reset signal line 37 illustrated in FIG. 4.

On the semiconductor substrate 40, an interlayer insulating layer 50 is stacked in such a manner as to cover the amplification transistor 21, the address transistor 23, and the reset transistor 22.

In addition, a line layer (not illustrated) may be disposed in the interlayer insulating layer 50. The line layer is formed of, for example, a metal such as copper, and may include, for example, lines such as the above-mentioned vertical signal line 27 in its part. Any number of the insulating layers in the interlayer insulating layer 50 and any number of layers included in the line layer disposed in the interlayer insulating layer 50 can be set.

In the interlayer insulating layer 50, a contact plug 53 connected to the gate electrode 21G of the amplification transistor 21, a contact plug 54 connected to the impurity region 22D of the reset transistor 22, a contact plug 51 connected to the first electrode 2, and a line 52 connecting the contact plug 51, the contact plug 54, and the contact plug 53 are disposed. This allows the impurity region 22D of the reset transistor 22 to be electrically connected to the gate electrode 21G of the amplification transistor 21. In the configuration illustrated in FIG. 5, the contact plugs 51, 53 and 54, the line 52, the gate electrode 21G of the amplification transistor 21 as well as the impurity region 22D of the reset transistor 22 constitute at least part of the charge storage node 34.

The charge detecting circuit 35 detects signal charge captured by the first electrode 2 and outputs a signal voltage. That is, the charge detecting circuit 35 reads a signal corresponding to charge generated in the photoelectric converter 10A. The charge detecting circuit 35 includes the amplification transistor 21, the reset transistor 22, and the address transistor 23 and is formed on the semiconductor substrate 40.

The amplification transistor 21 includes the impurity region 21D and the impurity region 21S, which are formed in the semiconductor substrate 40 and function respectively as a drain region and a source region, a gate insulating layer 21X formed on the semiconductor substrate 40, and the gate electrode 21G formed on the gate insulating layer 21X.

The reset transistor 22 includes the impurity region 22D and the impurity region 22S, which are formed in the semiconductor substrate 40 and function respectively as a drain region and a source region, a gate insulating layer 22X formed on the semiconductor substrate 40, and the gate electrode 22G formed on the gate insulating layer 22X.

The address transistor 23 includes the impurity regions 21S and 23S, which are formed in the semiconductor substrate 40 and function respectively as a drain region and a source region, a gate insulating layer 23X formed on the semiconductor substrate 40, and the gate electrode 23G formed on the gate insulating layer 23X. The impurity region 21S is connected to the amplification transistor 21 and the address transistor 23 in series.

On the interlayer insulating layer 50, the above-mentioned photoelectric converter 10A is disposed. In other words, in the present embodiment, the plurality of pixels 24, which constitute the pixel array PA, are formed on the semiconductor substrate 40. Then, the plurality of pixels 24 disposed two-dimensionally on the semiconductor substrate 40 form a photosensitive region. The distance between connected two pixels 24 (that is, the pixel pitch) may be, for example, around 2 m.

The photoelectric converter 10A includes a structure of the above-mentioned photoelectric conversion element 10.

A color filter 60 is formed above the photoelectric converter 10A, and a microlens 61 is formed above the color filter 60. The color filter 60 is formed, for example, as an on-chip color filter by patterning. As the material of the color filter 60, a photosensitive resin or the like in which a dye or a pigment is dispersed is used. The process temperature for forming the color filter 60 is, for example, greater than or equal to 170 degrees Celsius.

Even in the case of heating to greater than or equal to 170 degrees Celsius for forming the color filter 60, since the fullerene derivatives are unlikely to aggregate in the photoelectric conversion layer 4 of the photoelectric converter 10A, the reliability of the imaging device 100 can be improved.

The microlens 61 is formed, for example, as an on-chip microlens. As the material of the microlens 61, an ultraviolet light-sensitive material or the like is used.

The imaging device 100 can be manufactured by using a general semiconductor manufacturing process. In particular, in the case where a silicon substrate is used as the semiconductor substrate 40, the imaging device 100 can be manufactured by utilizing various silicon semiconductor processes.

Note that a system may be employed in which the positions of the electron blocking layer 3 and the hole blocking layer 5 are replaced, so that electrons are stored in the charge storage node 34 to be read, as mentioned above.

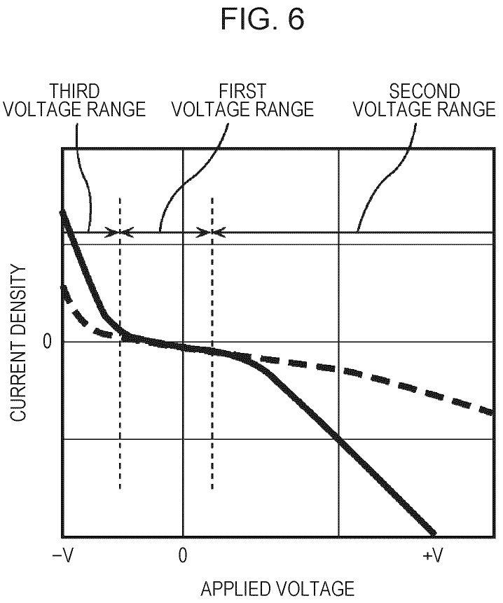

FIG. 6 is a diagram illustrating an example of schematic current-voltage (I-V) properties of the photoelectric conversion layer 4. In FIG. 6, a graph of a bold solid line represents illustrative I-V properties of the photoelectric conversion layer 4 when a voltage is applied between the first electrode 2 and the second electrode 6 in the state of being irradiated with light. In addition, in FIG. 6, an example of I-V properties of the photoelectric conversion layer 4 when a voltage is applied between the first electrode 2 and the second electrode 6 in the state of not being irradiated with light is also illustrated with a bold dashed line. In the present specification, the following description is made on the assumption that a voltage in the case of applying a positive voltage to the second electrode 6 is a bias voltage in the reverse direction and a voltage in the case of applying a negative voltage to the second electrode 6 is a bias voltage in the forward direction.

As illustrated in FIG. 6, the photocurrent properties of the photoelectric conversion layer 4 according to the present embodiment are schematically characterized by a first voltage range, a second voltage range, and a third voltage range. In the first voltage range, the dependency of change in current of the photoelectric conversion layer 4 on the voltage applied between the first electrode 2 and the second electrode 6 and the amount of light incident on the photoelectric conversion layer 4 is small. That is, in the first voltage range, a difference between a value of a current flowing in the case where there is light incident on the photoelectric conversion layer 4 and a value of a current flowing in the case where there is no light incident on the photoelectric conversion layer 4 can be regarded as being small. In the first voltage range, even when pairs of electrons and holes are generated by light being incident on the photoelectric conversion layer 4, since the absolute value of a voltage to be applied between the first electrode 2 and the second electrode 6 is not large, recombination of electrons and holes occurs before the electrons and the holes are separated. In addition, even when electrons and holes are separated, the electrons and the holes recombine via the trap level or the like during transport in the photoelectric conversion layer 4. Hence, it is also expected that the numbers of holes and electrons which flow into the electrodes become small.

In addition, the second voltage range in FIG. 6 is a voltage range of bias in the reverse direction, which is a region where the absolute value of output current density increases as the bias voltage in the reverse direction increases. That is, the second voltage range is a region where the value of a current increases as the amount of light incident on the photoelectric conversion layer 4 and the bias voltage applied between the first electrode 2 and the second electrode 6 increase.

In addition, the third voltage range is a voltage range of bias in the forward direction, which is a region where the output current density increases as the bias voltage in the forward direction increases. That is, the third voltage range is a region where the current increases as the bias voltage applied between the first electrode 2 and the second electrode 6 increases even when there is no light incident on the photoelectric conversion layer 4.

Since the photoelectric converter 10A of the imaging device 100 according to the present embodiment includes the photoelectric conversion layer 4 which has a first voltage range in which a difference between the value of a current flowing in the case where there is light incident on the photoelectric conversion layer 4 and the value of a current flowing in the case where there is no light incident on the photoelectric conversion layer 4 is small, the imaging device 100 can achieve a global shutter function while reducing a parasitic sensitivity.

### Operation of Imaging Device

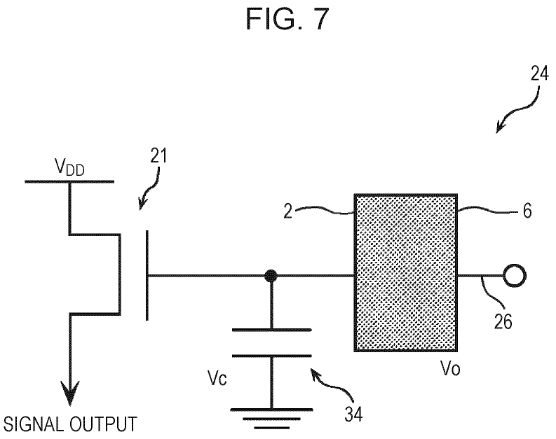

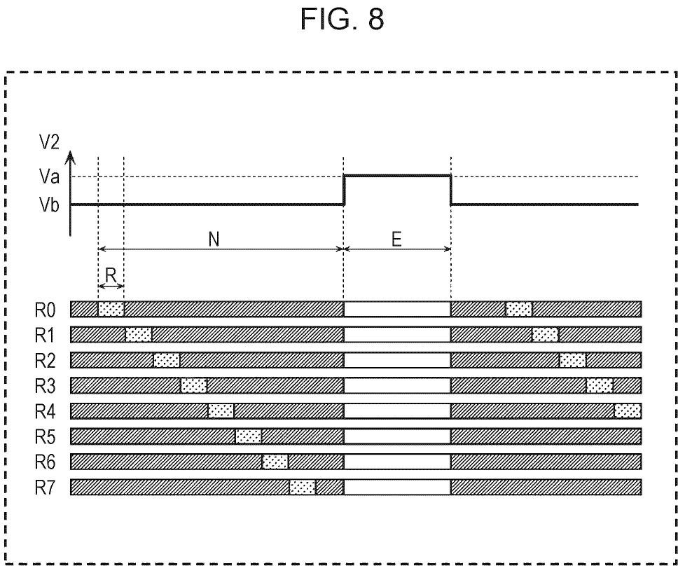

Next, an operation of the imaging device 100 will be described with reference to FIG. 7 and FIG. 8. Here, the case where holes are used as signal charge will be described.

FIG. 7 is a diagram illustrating part of a schematic circuit configuration of the pixel 24. Here, the case where one end of the charge storage node 34 is grounded, so that the potential is zero, is illustrated for simplifying the description. This state corresponds to, for example, the case where the feedback line 33 illustrated in FIG. 4 is set to 0 V. In this state, when the voltage of the charge storage node 34 is represented by Vc, Vc is zero.

A voltage supply circuit (not illustrated) supplies voltages different between an exposure time period and a non-exposure time period to the second electrode 6 via the counter electrode signal line 26. In the present specification, the “exposure time period” means a time period for storing one of an electron and a hole generated through photoelectric conversion as signal charge in the charge storage node 34. That is, the “exposure time period” may be referred to as a “charge storage time period”. In addition, in the present specification, a time period that is other than the exposure time period during the operation of the imaging device is referred to as the “non-exposure time period”. The “non-exposure time period” may be a time period when incidence of light on the photoelectric converter 10A is shut down, or may be a time period when light is incident on the photoelectric converter 10A but charge is substantially not stored in the charge storage node 34.

In the initial state, a potential difference between the first electrode 2 and the second electrode 6 of the photoelectric converter 10A, that is, a bias voltage applied to the photoelectric conversion layer 4, the electron blocking layer 3, and the hole blocking layer 5 is set to a value within the first voltage range. For example, the voltage supply circuit applies a voltage equal to the voltage of the first electrode 2 to the second electrode 6 by using the counter electrode signal line 26. Here, when the voltage to be applied to the second electrode 6 is represented by V2, V2 is supposed to be a reference voltage Vref. In this case, when the bias voltage to be applied to the photoelectric converter 10A is represented by Vo, Vo=V2−Vc, that is, Vo=0.

Next, an operation during the exposure time period will be described. At the start of the exposure time period, the voltage supply circuit applies the voltage V2 to the second electrode 6 by using the counter electrode signal line 26 such that a voltage within the second voltage range, that is, a bias voltage in the reverse direction is applied to the photoelectric converter 10A. For example, in the case where the photoelectric conversion layer 4 is formed of an organic semiconductor material, V2 is a voltage of several V to around 10 V at a maximum. This allows holes of an amount corresponding to the amount of light incident on the photoelectric conversion layer 4 to be stored in the charge storage node 34 of each pixel 24 as signal charge.

Next, an operation during the non-exposure time period will be described. After the end of the exposure time period, the voltage supply circuit applies the voltage V2 to the second electrode 6 by using the counter electrode signal line 26 such that a voltage within the first voltage range is applied to the photoelectric converter 10A. For example, the voltage V2 to be applied to the second electrode 6 is set to the reference voltage Vref. In the charge storage node 34 of each pixel 24, holes corresponding to the amount of light which has been incident on the photoelectric conversion layer 4 during the exposure time period have been stored, and the value of Vc varies among the pixels 24. Since Vo=V2-Vc, in the pixel 24 which has not been exposed and whose Vc has not been changed, Vo also becomes zero. However, in the pixel 24 whose Vc has been changed, Vo does not become zero. In the case where the width of the first voltage range is ensured in a sufficiently wide voltage range, even when the value of Vc varies among the pixels 24, the voltage V2 can be set such that the voltage Vo to be applied to the photoelectric converter 10A in each pixel 24 falls within the first voltage range. The variation of values of the voltage Vc which fall within the first voltage range corresponds to the size of the dynamic range. For example, in the case where the width of the first voltage range is greater than or equal to 0.5 V, a dynamic range of greater than or equal to 80 dB, which corresponds to the eyes of humans, can be ensured in an imaging device having a conversion gain of 50 V/e⁻.

In the state where the voltage V2 which makes the voltage Vo fall within the first voltage range is being applied to the second electrode 6, even if light is incident on the pixel 24, holes are unlikely to move to the charge storage node 34. In addition, holes stored in the charge storage node 34 are unlikely to be discharged to the first electrode 2, or charge supplied from the voltage supply circuit via the second electrode 6 is unlikely to flow into the charge storage node 34.

Therefore, holes stored in the charge storage node 34 of each pixel 24 are held while being maintained in an amount corresponding to the amount of light incident on the photoelectric conversion layer 4. That is, holes stored in the charge storage node 34 of the pixel 24 can be held as long as the holes in the charge storage node 34 are not reset even when light is again incident on the photoelectric conversion layer 4. Hence, even when a reading operation is conducted successively for each row in the non-exposure time period, new holes are unlikely to be stored between the reading operations. Hence, for example, rolling distortion does not occur, unlike rolling shutter. Therefore, for example, it is possible to achieve a global shutter function with a simple pixel circuit such as the pixels 24 without including transfer transistors or additional storage capacitances. Since the pixel circuit is simple, it is possible to advantageously make the pixels 24 finer in the imaging device 100.

FIG. 8 is a timing chart illustrating an example of the voltage V2 applied to the second electrode 6 of the photoelectric converter 10A and timings of operations in each of rows of the pixel array PA of the imaging device 100. FIG. 8 illustrates only a change in the voltage V2 and the timings of exposure and signal reading of each of the rows in the pixel array PA which are indicated by R0 to R7 for understandability. As illustrated in FIG. 8, in the imaging device 100, during a non-exposure time period N, a voltage Vb is applied to the second electrode 6 as the voltage V2 which makes the voltage Vo fall within the first voltage range, while during an exposure time period E, a voltage Va is applied to the second electrode 6 as the voltage V2 which makes Vo fall within the second voltage range. As illustrated in FIG. 8, during the non-exposure time period N, signal reading R on the rows of R0 to R7 is successively conducted. In addition, the timings of start and end of the exposure time period E coincide among all the rows of R0 to R7. That is, the imaging device 100 achieves a global shutter function of simultaneously exposing all the rows of the pixel array PA while successively reading signals of the pixels 24 of each of the rows.

Note that the imaging device 100 may be driven with a rolling shutter method.

As described above, the imaging device 100 according to the present embodiment includes the photoelectric conversion element 10 (the photoelectric converter 10A) including the first electrode 2, the second electrode 6, and the photoelectric conversion layer 4 located between the first electrode 2 and the second electrode 6. The photoelectric conversion layer 4 contains the donor semiconductor, the first fullerene derivative, the second fullerene derivative, and the polymer. This configuration suppresses aggregations and crystallization of the fullerene derivatives. Hence, changes in properties of the photoelectric conversion element 10 are suppressed, and the imaging device 100 including the photoelectric conversion element 10, which has an improved reliability, is achieved.

### EXAMPLES

Hereinafter, the photoelectric conversion element and the fullerene derivative solution according to the present disclosure will be specifically described by using Examples; however, the present disclosure is not limited to the following Examples at all.

Specifically, photoelectric conversion elements according to the embodiments of the present disclosure and photoelectric conversion elements for comparison of properties were fabricated, and property evaluation was conducted. In addition, particle size distributions were measured for evaluating the states of aggregations of the fullerene derivatives in the fullerene derivative solutions.

### Fabrication of Photoelectric Conversion Elements

First, property evaluation of photoelectric conversion elements will be described. Photoelectric conversion elements in Examples and Comparative Examples were fabricated in accordance with the following steps.

### Example 1

A glass substrate having a thickness of 0.7 mm which had an ITO film having a thickness of 150 nm as a first electrode on one principal surface thereof was prepared. An electron blocking layer was formed by applying 10 mg/ml of an o-xylene solution of VNPB (N4,N4′-di(naphthalen-1-yl)-N4,N4′-bis(4-vinylphenyl)biphenyl-4,4′-diamine, produced by LUMTEC) on the first electrode by a spin coating method in a glovebox having a nitrogen atmosphere. After the film formation, VNPB was cross-linked by heating at 200° C. for 50 minutes by using a hot plate to insolubilize the electron blocking layer.

Thereafter, a mixed film which served as a photoelectric conversion layer was formed by a spin coating method using a fullerene derivative solution of toluene solvent containing a naphthalocyanine derivative as the donor organic semiconductor, [60]PCBM and [70]PCBM as the first fullerene derivative and the second fullerene derivative, which were the acceptor organic semiconductor, and polyvinylcarbazole as the polymer. The thickness of the mixed film thus obtained was about 250 nm. In addition, the ratio by weight of naphthalocyanine derivative, [60]PCBM, [70]PCBM, and polyvinylcarbazole in the fullerene derivative solution was 17.1:54.9:13.7:14.3. In addition, the weight average molecular weight of the polyvinylcarbazole used was 90000.

Note that as the naphthalocyanine derivative, a naphthalocyanine derivative having a substituent such as an alkyl group in the skeleton is appropriate because it is easily dissolved, and a compound represented by the following structural formula (1) was used in the present Example.

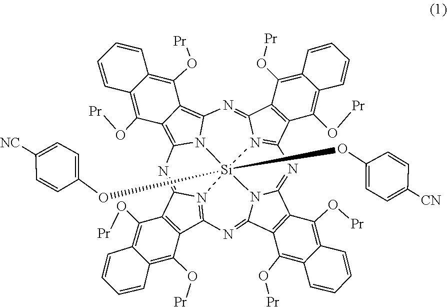

Moreover, a film of Chloroaluminum Phthalocyanine (ClAlPc) was formed with a thickness of 30 nm as the hole blocking layer through a shadow mask made of a metal by a vacuum deposition method.

Thereafter, an ITO film was formed with a film thickness of 30 nm as the second electrode on the hole blocking layer by a sputtering method. In this way, a photoelectric conversion element of Example 1 was obtained.

### Example 2

A photoelectric conversion element of Example 2 was obtained by conducting the same steps as in Example 1 except that a photoelectric conversion layer was formed by using a fullerene derivative solution in which the ratio by weight of naphthalocyanine derivative, [60]PCBM, [70]PCBM, and polyvinylcarbazole was set to 18.2:58.2:14.5:9.1.

### Example 3

A photoelectric conversion element of Example 3 was obtained by conducting the same steps as in Example 1 except that a photoelectric conversion layer was formed by using a fullerene derivative solution in which the ratio by weight of naphthalocyanine derivative, [60]PCBM, [70]PCBM, and polyvinylcarbazole was set to 15.0:48.0:12.0:25.0.

### Comparative Example 1

A photoelectric conversion element of Comparative Example 1 was obtained by conducting the same steps as in Example 1 except that a photoelectric conversion layer was formed by using a fullerene derivative solution which did not contain [70]PCBM in which the ratio by weight of naphthalocyanine derivative, [60]PCBM, and polyvinylcarbazole was set to 17.1:68.6:14.3.

### Comparative Example 2

A photoelectric conversion element of Comparative Example 2 was obtained by conducting the same step as in Example 1 except that a photoelectric conversion layer was formed by using a fullerene derivative solution which did not contain polyvinylcarbazole in which the ratio by weight of naphthalocyanine derivative, [60]PCBM, and [70]PCBM was set to 20.0:64.0:16.0.

### Property Evaluation of Photoelectric Conversion Element

As the property evaluation of the photoelectric conversion elements thus obtained, evaluations of dark current and photoelectric conversion efficiency were conducted by the following methods. In addition, in the property evaluation, each photoelectric conversion element fabricated was heated at 200° C. for 50 minutes by using a hot plate in a glovebox, and the property evaluation of the photoelectric conversion element before and after the heating was conducted.

### Measurement of Photoelectric Conversion Efficiency

The photoelectric conversion efficiency of each obtained photoelectric conversion element was measured. Specifically, the photoelectric conversion element was introduced into a measurement jig, which was able to be tightly closed in a glovebox under a nitrogen atmosphere, and the external quantum efficiency was measured under a voltage condition of 10 V by using a long wavelength-sensitive spectral sensitivity measurement device (manufactured by Bunkoukeiki Co., Ltd., CEP-25RR). The results of measuring the external quantum efficiencies at a wavelength of 940 nm are shown in Table 1. Note that Table 1 also shows the percentages by weight of the materials in each photoelectric conversion layer.

### Measurement of Dark Current

The dark current of each obtained photoelectric conversion element was measured. The measurement was conducted in a glovebox under a nitrogen atmosphere by using a B1500A semiconductor device parameter analyzer (manufactured by Keysight Technologies). The values of dark currents when a voltage of 10 V was applied are shown in Table 1.

TABLE 1

| | | | | | External quantum | | Dark current | |
|---|---|---|---|---|---|---|---|---|
| | Percentages by weight in photoelectric conversion layer | | | | efficiency | | (×10⁻⁶ mA/cm²) | |
| | Naphthalocyanine | | | | Before | After | Before | After |
| | derivative | [60]PCBM | [70]PCBM | Polyvinylcarbazole | heating | heating | heating | heating |
| Example 1 | 17.1% | 54.9% | 13.7% | 14.3% | 25.1% | 24.8% | 8.9 | 11.2 |
| Example 2 | 18.2% | 58.2% | 14.5% | 9.1% | 30.2% | 28.7% | 9.6 | 24.9 |
| Example 3 | 15.0% | 48.0% | 12.0% | 25.0% | 18.5% | 18.4% | 1.6 | 3.3 |
| Comparative | 17.1% | 68.6% | — | 14.3% | 28.9% | 26.4% | 7.3 | 38.2 |
| Example 1 | | | | | | | | |
| Comparative | 20.0% | 64.0% | 16.0% | — | 37.5% | broken | 13.2 | broken |
| Example 2 | | | | | | | | |

As shown in Table 1, in the photoelectric conversion element of Comparative Example 1 including the photoelectric conversion layer which used only one type of fullerene derivative and a polymer, the dark current significantly increased after the heating at 200° C. In addition, in the photoelectric conversion element of Comparative Example 2 including the photoelectric conversion layer which did not contain a polymer, wrinkles, cracks, and the like are generated in the photoelectric conversion layer after the heating at 200° C., so that breakage of the photoelectric conversion element occurred. On the other hand, in the photoelectric conversion elements of Examples 1 to 3 each including the photoelectric conversion layer using two types of fullerene derivatives and a polymer, breakage of the photoelectric conversion elements did not occur even after the heating at 200° C., and an increase in dark current was also suppressed. This is considered that aggregations and crystallization of the fullerene derivatives due to heating were suppressed because the photoelectric conversion layers each contained two types of fullerene derivatives and a polymer.

### Fabrication of Solution for Particle Size Distribution Measurement

Next, evaluation of the aggregation states of fullerene derivatives will be described. Fullerene derivative solutions for evaluation of the aggregation states of the fullerene derivatives were fabricated by the following steps.

### Example 4

[60]PCBM, [70]PCBM, and polyvinylcarbazole were each weighed such that the ratio by weight became 76.8:19.2:4.0 and the total weight of the two types of fullerene derivatives became 24 mg. These materials were placed in a glass container washed in a clean room environment. Moreover, after a magnetic stirrer was placed, 1 ml of anisole was added as a solvent. The weight average molecular weight of the polyvinylcarbazole used was 90000. The solution in the glass container was stirred for 12 hours in a glovebox having a nitrogen atmosphere to obtain a fullerene derivative solution of Example 4.

### Example 5

A fullerene derivative solution of Example 5 was obtained by conducting the same steps as in Example 4 except that [60]PCBM, [70]PCBM, and polyvinylcarbazole were each weighed such that the ratio by weight became 71.1:17.8:11.1.

### Example 6

A fullerene derivative solution of Example 6 was obtained by conducting the same steps as in Example 4 except that [60]PCBM, [70]PCBM, and polyvinylcarbazole were each weighed such that the ratio by weight became 66.2:16.6:17.2.

### Example 7

A fullerene derivative solution of Example 7 was obtained by conducting the same steps as in Example 4 except that [60]PCBM, [70]PCBM, and polyvinylcarbazole were each weighed such that the ratio by weight became 56.5:14.1:29.4.

### Example 8

A fullerene derivative solution of Example 8 was obtained by conducting the same steps as in Example 4 except that [60]PCBM, [70]PCBM, and polyvinylcarbazole were each weighed such that the ratio by weight became 63.5:7.1:29.4.

### Example 9

A fullerene derivative solution of Example 9 was obtained by conducting the same steps as in Example 4 except that [60]PCBM, [70]PCBM, and polyvinylcarbazole were each weighed such that the ratio by weight became 49.4:21.2:29.4.

### Example 10

A fullerene derivative solution of Example 10 was obtained by conducting the same steps as in Example 6 except that chloroform was used instead of anisole.

### Example 11

A fullerene derivative solution of Example 11 was obtained by conducting the same steps as in Example 4 except that poly(triarylamine) was used instead of polyvinylcarbazole. The poly(triarylamine) used is specifically poly [bis(4-phenyl)(2,4,6-trimethylphenyl) amine]. In addition, the weight average molecular weight of the poly(triarylamine) used was 250000.

### Example 12

A fullerene derivative solution of Example 12 was obtained by conducting the same steps as in Example 6 except that phenyl-C₆₁-butyric acid butyl ester ([60]PCBB) was used instead of [70]PCBM.

### Example 13

A fullerene derivative solution of Example 13 was obtained by conducting the same steps as in Example 6 except that phenyl-C₆₁-butyric acid octyl ester ([60]PCBO) was used instead of [70]PCBM.

### Example 14

A fullerene derivative solution of Example 14 was obtained by conducting the same steps as in Example 6 except that phenyl-C₆₁-butyric acid dodecyl ester ([60]PCBD) was used instead of [70]PCBM.

### Comparative Example 3

A fullerene derivative solution of Comparative Example 3 was obtained by conducting the same steps as in Example 4 except that [70]PCBM was not used and [60]PCBM and polyvinylcarbazole were each weighed such that the ratio by weight became 82.8:17.2 and the weight of the fullerene derivative became 24 mg.

### Comparative Example 4

A fullerene derivative solution of Comparative Example 4 was obtained by conducting the same steps as in Comparative Example 3 except that [60]PCBM and polyvinylcarbazole were each weighed such that the ratio by weight became 70.6:29.4.

### Comparative Example 5

A fullerene derivative solution of Comparative Example 5 was obtained by conducting the same steps as in Example 4 except that [60]PCBM was not used and [70]PCBM and polyvinylcarbazole were each weighed such that the ratio by weight became 82.8:17.2.

### Comparative Example 6

A fullerene derivative solution of Comparative Example 6 was obtained by conducting the same steps as in Example 10 except that [70]PCBM and polyvinylcarbazole were not used and only [60]PCBM was weighed in 24 mg.

### Comparative Example 7

A fullerene derivative solution of Comparative Example 7 was obtained by conducting the same steps as in Example 10 except that polyvinylcarbazole was not used and [60]PCBM and [70]PCBM were each weighed such that the ratio by weight became 80.0:20.0.

### Comparative Example 8

A fullerene derivative solution of Comparative Example 8 was obtained by conducting the same steps as in Example 12 except that polyvinylcarbazole was not used and [60]PCBM and [60]PCBB were each weighed such that the ratio by weight became 80.0:20.0.

### Comparative Example 9

A fullerene derivative solution of Comparative Example 9 was obtained by conducting the same steps as in Example 13 except that polyvinylcarbazole was not used and [60]PCBM and [60]PCBO were each weighed such that the ratio by weight became 80.0:20.0.

### Comparative Example 10

A fullerene derivative solution of Comparative Example 10 was obtained by conducting the same steps as in Example 14 except that polyvinylcarbazole was not used and [60]PCBM and [60]PCBD were each weighed such that the ratio by weight became 80.0:20.0.

### Measurement of Particle Size Distribution

The particle size distribution of each obtained fullerene derivative solution was measured by using a nanoparticle size measuring device (manufactured by Microtrac, Nanotrac Wave II) under an environment of 25° C. As the result of measuring the number-based particle size distribution (so-called number distribution), d50 (median size) and the presence or absence of particles of greater than or equal to 1 μm are shown in Table 2. As the evaluation of the presence or absence of particles of greater than or equal to 1 μm in Table 2, the case where the number of particles having a particle size of greater than or equal to 1 μm was less than 5% of the total number of particles is expressed as “Absent” as the case where particles having a particle size of greater than or equal to 1 μm were substantially absent, while the case where the number of particles having a particle size of greater than or equal to 1 μm was greater than or equal to 5% of the total number of particles is expressed as “Present” as the case where particles having a particle size of greater than or equal to 1 μm were substantially present. Note that Table 2 also shows the types of materials and solvent contained in each fullerene derivative solution as well as the percentages by weight of the materials. In addition, in Table 2, polyvinylcarbazole is expressed as “PVK”, and poly(triarylamine) is expressed as “PTAA”.

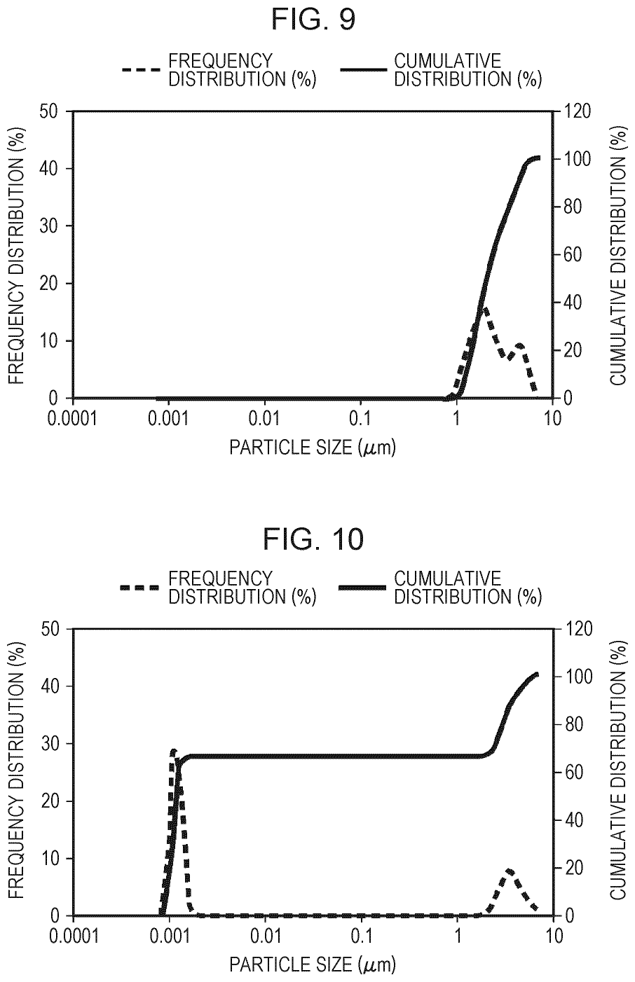

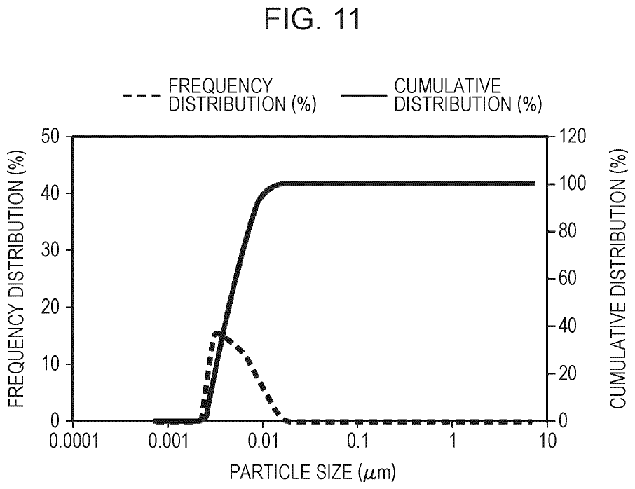

In addition, the particle size distributions of Comparative Example 6, Comparative Example 7, and Example 10 are illustrated in FIG. 9, FIG. 10, and FIG. 11, respectively. In FIG. 9 to FIG. 11, the horizontal axis indicates the particle size expressed by log and the vertical axes indicate the cumulative distribution (%) and the frequency distribution (%) of the number of particles. In FIG. 9 to FIG. 11, the cumulative distribution of the number of particles is indicated by a solid line and the frequency distribution of the number of particles is indicated by a dashed line.

TABLE 2

| | | | | | | | | | Presence |
|---|---|---|---|---|---|---|---|---|---|
| | Types and percentages by weight of materials in fullerene derivative solution | | | | | | | | of particles |
| | First fullerene | | Second fullerene | | | | | | of greater |
| | derivative | | derivative | | Polymer | | | | than or |
| | Material | Percentage | Material | Percentage | Material | Percentage | | d50 | equal to 1 |
| | type | by weight | type | by weight | type | by weight | Solvent | (μm) | μm |
| Example 4 | [60]PCBM | 76.8% | [70]PCBM | 19.2% | PVK | 4.0% | Anisole | 0.0019 | Absent |
| Example 5 | [60]PCBM | 71.1% | [70]PCBM | 17.8% | PVK | 11.1% | Anisole | 0.0031 | Absent |
| Example 6 | [60]PCBM | 66.2% | [70]PCBM | 16.6% | PVK | 17.2% | Anisole | 0.0028 | Absent |
| Example 7 | [60]PCBM | 56.5% | [70]PCBM | 14.1% | PVK | 29.4% | Anisole | 0.0047 | Absent |
| Example 8 | [60]PCBM | 63.5% | [70]PCBM | 7.1% | PVK | 29.4% | Anisole | 0.0077 | Absent |
| Example 9 | [60]PCBM | 49.4% | [70]PCBM | 21.2% | PVK | 29.4% | Anisole | 0.0029 | Absent |
| Example 10 | [60]PCBM | 66.2% | [70]PCBM | 16.6% | PVK | 17.2% | Chloroform | 0.0045 | Absent |
| Example 11 | [60]PCBM | 76.8% | [70]PCBM | 19.2% | PTAA | 4.0% | Anisole | 0.0014 | Absent |
| Example 12 | [60]PCBM | 66.2% | [60]PCBB | 16.6% | PVK | 17.2% | Anisole | 0.0051 | Absent |
| Example 13 | [60]PCBM | 66.2% | [60]PCBO | 16.6% | PVK | 17.2% | Anisole | 0.0105 | Absent |
| Example 14 | [60]PCBM | 66.2% | [60]PCBD | 16.6% | PVK | 17.2% | Anisole | 0.0072 | Absent |
| Comparative | [60]PCBM | 82.8% | — | — | PVK | 17.2% | Anisole | 0.0098 | Present |
| Example 3 | | | | | | | | | |
| Comparative | [60]PCBM | 70.6% | — | — | PVK | 29.4% | Anisole | 5.62 | Present |
| Example 4 | | | | | | | | | |
| Comparative | [70]PCBM | 82.8% | — | — | PVK | 17.2% | Anisole | 0.0025 | Present |
| Example 5 | | | | | | | | | |
| Comparative | [60]PCBM | 100.0% | — | — | PVK | 0.0% | Chloroform | 1.9873 | Present |
| Example 6 | | | | | | | | | |
| Comparative | [60]PCBM | 80.0% | [70]PCBM | 20.0% | PVK | 0.0% | Chloroform | 0.0012 | Present |
| Example 7 | | | | | | | | | |
| Comparative | [60]PCBM | 80.0% | [60]PCBB | 20.0% | PVK | 0.0% | Anisole | 5.58 | Present |
| Example 8 | | | | | | | | | |
| Comparative | [60]PCBM | 80.0% | [60]PCBO | 20.0% | PVK | 0.0% | Anisole | 2.98 | Present |
| Example 9 | | | | | | | | | |
| Comparative | [60]PCBM | 80.0% | [60]PCBD | 20.0% | PVK | 0.0% | Anisole | 5.81 | Present |
| Example 10 | | | | | | | | | |

As shown in Table 2, it can be seen that in the fullerene derivative solutions of Example 4 to Example 14 each of which contained two types of fullerene derivatives and a polymer, particles were dispersed in nanosize and also particles of greater than or equal to 1 tm were substantially absent. On the other hand, it can be seen that in the fullerene derivative solutions of Comparative Examples 3 to 5 each of which contained only one type of fullerene derivative and a polymer as well as the fullerene derivative solutions of Comparative Examples 6 to 10 each of which did not contain a polymer, particles in micron size were observed and the fullerene derivative aggregated.

In addition, similar things can be seen from the particle size distributions illustrated in FIG. 9 to FIG. 11. Specifically, as illustrated in FIG. 9, in the fullerene derivative solution of Comparative Example 6 which contained [60]PCBM and a solvent, most particles were of greater than or equal to 1 m. In addition, as illustrated in FIG. 10, in the fullerene derivative solution of Comparative Example 7 which was obtained by further adding [70]PCBM different from [60]PCBM to the fullerene derivative solution of Comparative Example 6, although a large number of particles dispersed in nanosize were present and d50 was small, particles of greater than or equal to 1 μm were also present at greater than or equal to 30% of the entire particles. In contrast, as illustrated in FIG. 11, the fullerene derivative solution of Example 10 in which polyvinylcarbazole was further added as a polymer in addition to [60]PCBM and [70]PCBM, particles of greater than or equal to 1 μm were absent, and most of the particles were particles of less than or equal to 0.01 m (that is, 10 nm). Hence, it can be seen that in the fullerene derivative solution of Example 10 which contained two types of fullerene derivatives and a polymer, aggregations of the fullerene derivatives were suppressed as compared with Comparative Example 6 and Comparative Example 7.

From the above-described results, it is obvious that by using a fullerene derivative solution which contains two types of fullerene derivatives and a polymer, aggregations do not occur even when a photoelectric conversion layer of a photoelectric conversion element is formed as shown in Table 1, and a photoelectric conversion element excellent in reliability can be obtained.

In addition, the fullerene derivative solutions of Examples 4 to 14 are fullerene derivative solutions that contained no donor semiconductor, and solutions for forming photoelectric conversion layers having properties which meet demands of devices can be fabricated by combining these fullerene derivative solutions with not only the donor semiconductors used in Examples but also various donor semiconductors.

Although the photoelectric conversion element, the imaging device, and the fullerene derivative solution according to the present disclosure have been described above based on the embodiments and Examples, the present disclosure is not limited to these embodiments and Examples. Embodiments obtained by applying various modifications which a person skilled in the art can come up with to the embodiments and Examples as well as other embodiments configured by combining some constituents in the embodiments and Examples without departing from the gist of the present disclosure are also encompassed by the scope of the present disclosure.

For example, although in the above-described embodiments, the fullerene derivative solution is used for forming the photoelectric conversion layer 4, the present disclosure is not limited to this. For example, the fullerene derivative solution may be used for forming another semiconductor layer such as the electron blocking layer 3, the hole blocking layer 5, or the charge transport layer.

In addition, for example, although in the above-described embodiments, an example in which the photoelectric conversion element 10 is used in the imaging device 100 has been described, the present disclosure is not limited to this. The photoelectric conversion element 10 may be used in another device such as an optical sensor or a solar cell.

The photoelectric conversion element, the imaging device, and the fullerene derivative solution according to the present disclosure are useful for image sensors and the like used in imaging devices represented by digital cameras.

What is claimed is:

1. A photoelectric conversion element comprising:
a first electrode;
a second electrode opposite to the first electrode; and
a photoelectric conversion layer located between the first electrode and the second electrode, wherein
the photoelectric conversion layer contains a donor semiconductor, a first fullerene derivative, a second fullerene derivative different in molecular structure from the first fullerene derivative, and a polymer, and
the polymer contains at least one selected from the group consisting of polyvinylcarbazole, poly(triarylamine), polyfluorene, a polyvinylcarbazole derivative, a poly(triarylamine) derivative, and a polyfluorene derivative.

2. The photoelectric conversion element according to claim 1, wherein
the first fullerene derivative is one selected from the group consisting of phenyl-C₆₁-butyric acid methyl ester, phenyl-C₇₁-butyric acid methyl ester, phenyl-C₆₁-butyric acid butyl ester, phenyl-C₆₁-butyric acid octyl ester, and phenyl-C₆₁-butyric acid dodecyl ester, and
the second fullerene derivative is another one selected from the group consisting of phenyl-C₆₁-butyric acid methyl ester, phenyl-C₇₁-butyric acid methyl ester, phenyl-C₆₁-butyric acid butyl ester, phenyl-C₆₁-butyric acid octyl ester, and phenyl-C₆₁-butyric acid dodecyl ester.

3. The photoelectric conversion element according to claim 1, wherein the number of carbon atoms of a fullerene skeleton of the first fullerene derivative is different from the number of carbon atoms of a fullerene skeleton of the second fullerene derivative.

4. The photoelectric conversion element according to claim 1, wherein
the first fullerene derivative is phenyl-C₆₁-butyric acid methyl ester, and
the second fullerene derivative is phenyl-C₇₁-butyric acid methyl ester.

5. The photoelectric conversion element according to claim 4, wherein a ratio by weight of the second fullerene derivative to the first fullerene derivative is greater than or equal to 10/90 and less than or equal to 30/70.

6. The photoelectric conversion element according to claim 1, wherein a ratio by weight of the polymer to a total weight of the first fullerene derivative and the second fullerene derivative is greater than or equal to 1/30 and less than or equal to 30/70.

7. The photoelectric conversion element according to claim 1, wherein the polymer is an organic semiconductor.

8. The photoelectric conversion element according to claim 1, wherein a weight average molecular weight of the polymer is greater than or equal to 50000.

9. An imaging device comprising:
a photoelectric converter that generates charge through photoelectric conversion; and
a charge detecting circuit that is connected to the photoelectric converter, wherein
the photoelectric converter includes the photoelectric conversion element according to claim 1.

10. A fullerene derivative solution comprising:
a first fullerene derivative;
a second fullerene derivative different in molecular structure from the first fullerene derivative;
a polymer; and
a solvent, wherein
the number of particles each having a particle size of greater than or equal to 1 m is less than 5% of a total number of particles.

11. The fullerene derivative solution according to claim 10, wherein
the first fullerene derivative is one selected from the group consisting of phenyl-C₆₁-butyric acid methyl ester, phenyl-C₇₁-butyric acid methyl ester, phenyl-C₆₁-butyric acid butyl ester, phenyl-C₆₁-butyric acid octyl ester, and phenyl-C₆₁-butyric acid dodecyl ester, and
the second fullerene derivative is another one selected from the group consisting of phenyl-C₆₁-butyric acid methyl ester, phenyl-C₇₁-butyric acid methyl ester, phenyl-C₆₁-butyric acid butyl ester, phenyl-C₆₁-butyric acid octyl ester, and phenyl-C₆₁-butyric acid dodecyl ester.

12. The fullerene derivative solution according to claim 10, wherein the number of carbon atoms of a fullerene skeleton of the first fullerene derivative is different from the number of carbon atoms of a fullerene skeleton of the second fullerene derivative.

13. The fullerene derivative solution according to claim 10, wherein
the first fullerene derivative is phenyl-C₆₁-butyric acid methyl ester, and
the second fullerene derivative is phenyl-C₇₁-butyric acid methyl ester.

14. The fullerene derivative solution according to claim 13, wherein a ratio by weight of the second fullerene derivative to the first fullerene derivative is greater than or equal to 10/90 and less than or equal to 30/70.

15. The fullerene derivative solution according to claim 10, wherein a ratio by weight of the polymer to a total weight of the first fullerene derivative and the second fullerene derivative is greater than or equal to 1/30 and less than or equal to 30/70.

16. The fullerene derivative solution according to claim 10, wherein the polymer is an organic semiconductor.

17. The fullerene derivative solution according to claim 10, wherein a weight average molecular weight of the polymer is greater than or equal to 50000.

18. The fullerene derivative solution according to claim 10, wherein the polymer contains at least one selected from the group consisting of polyvinylcarbazole, poly(triarylamine), polyfluorene, a polyvinylcarbazole derivative, a poly(triarylamine) derivative, and a polyfluorene derivative.

19. The fullerene derivative solution according to claim 10, wherein the solvent contains at least one selected from the group consisting of benzene, toluene, xylene, anisole, chlorobenzene, chloronaphthalene, chlorophenol, tetralin, and chloroform.

20. A photoelectric conversion element comprising:
a first electrode;
a second electrode opposite to the first electrode; and
a photoelectric conversion layer located between the first electrode and the second electrode, wherein
the photoelectric conversion layer is formed by using the fullerene derivative solution according to claim 10.
